(19) United States
(12) Patent Application Publication
(10) Pub. No.: US 2011/0007462 A1
(43) Pub. Date: Jan. 13, 2011

(54) Housing for an electrical appliance

(75) Inventors: Urs PROBST, Zug (CH); Ladislav KUCERA, Thalwil (CH)

Correspondence Address: BIRCH STEWART KOLASCH & BIRCH, PO BOX 747, FALLS CHURCH, VA, 22040-0747, US

(73) Assignee: CTC Analytics AG, Zwingen (CH)

(21) Appl. No.: 12/833,646

(22) Filed: Jul. 9, 2010

(30) Foreign Application Priority Data
Jul. 10, 2009 (DE) 10 2009 032 522.0

(51) Int. Cl. H05K 5/02; H05K 5/00

(52) U.S. Cl. 361/679.01; 312/223.1

(57) ABSTRACT

A housing is provided for an electrical appliance having a cavity in a flange (311) of the housing for holding an electronic assembly (304). The cavity has walls which each have a depression (310) which are designed such that elastically deformable tabs (303) on a housing cover, which at least partially bounds the cavity on the outside and, for example, ends with the upper edge of the walls or rests on this upper edge, can latch into these depressions.

The invention relates to a housing for an electrical appliance, for example for an electric motor. Appliances such as these are frequently controlled or operated with the aid of an electronic assembly which, for reasons which depend on the respective type of appliance or on the application, should be accommodated together with the appliance in one housing.

For example, in the case of a stepping motor which is intended to be controlled with the aid of a magnetic encoder disk which is fitted to the motor shaft, it is expedient to arrange an electronic assembly in the immediate vicinity of this encoder disk, on which electronic assembly a sensor which measures the rotation movement or the angular position of the encoder disk is also arranged.

One such arrangement is described, for example, in DE 195 27 981 A1, which discloses an electronically commutated electric motor which is operated with the aid of a magnetic sensor system for commutation control.

By way of example, DE 102 36 700 A1 describes a similar arrangement in the form of an apparatus for holding and fixing a sensor apparatus in a direct-current motor.

In these situations and other situations, it is desirable to fit the electronic assembly to the appliance in a manner which links adequate protection of the assembly with assembling which is as simple as possible.

DE 39 30 144 A discloses an electric motor, a motor housing in the form of a pot, a gearbox housing which closes an end face of the motor housing with an end frame and has a gearbox pot for holding gearbox elements and a cover which closes the gearbox pot, and a holder, which is located in a pocket in the gearbox pot, for an electrical component which is conductively connected to a sliding carbon brush arranged in the motor housing.

DE 10 38 285 A1 describes an electrical drive device having a drive housing, having a housing cover which can be fitted axially to the drive housing, having an armature shaft, having supply means which supply electric current to the drive device, and having detection means which, in particular, detect the rotation speed of the armature shaft. One characteristic of this drive device is that the housing cover provides at least one cutout for holding plug and/or holding housings, which are intended for electrical connection and/or for holding the supply and/or detection means.

DE 196 37 192 C2 discloses an electric motor having an integrated electronics unit connected to the stator winding. A housing in the form of a pot is arranged at the end of an external-rotor motor that faces away from the closed bottom face of the rotor bell, the pot base of which housing faces the electric motor, and the open pot face of which can be closed axially on the outside by a housing cover, for example by forming flanges, by peening, or by screw connection. The housing in the form of a pot can be fixed by attachment means, for example by screwing to the stator, preferably to the bearing which is in the form of a spoke, and forms a load-bearing motor component, in particular in the form of a flange part with attachment lugs distributed over the circumference in order to hold the electric motor in a motor holder, which is not shown here in any more detail. Within the housing, preferably in the vicinity of the housing base, a printed circuit board is held, in order to hold an electronics unit as a control and power part for the electric motor, for example by means of screws. The semiconductor components in the electronics unit are pressed against walls of the housing by clamping springs on the cover side, when the housing is closed by the housing cover.

Depending on the specific requirements of the respective application, these known solutions are associated with various advantages and disadvantages.

The present invention is based on the object of specifying a housing structure which complies better with the requirements of at least some of the applications. This object is achieved by a housing according to claim 1.

A housing for an electrical appliance having a cavity in a flange of the housing for holding an electronic assembly is provided for this purpose. The cavity has walls which each have a depression which are designed such that elastically deformable tabs on a housing cover, which at least partially bounds the cavity on the outside—for example ends with the upper edge of the walls or rests on this upper edge—can latch into these depressions. In this case, all the walls may possibly, but need not necessarily, have such depressions.

For the purposes of the description of the present invention, a housing means a fixed surround which protectively surrounds an appliance and an electronic assembly, which is used with this appliance or belongs to this appliance, and possibly further components, and possibly supports an arrangement of these components as appropriate for the function. Depending on the robustness requirements for the specific situation, such housings may be manufactured from materials of appropriate strength, such as metal, plastic or similar materials.

For the purposes of the description of the present invention, an electrical appliance means any apparatus which receives, emits, stores or converts electrical energy. Examples of electrical appliances are electric motors, generators, transformers, energy stores, signal-processing apparatuses, information-processing apparatuses, or other devices which receive, emit, store or convert electrical energy.

For the purposes of the description of the present invention, a cavity means a region of the three-dimensional space which is at least partially surrounded or bounded by walls or by at least one wall which is not flat. In this case, the walls or the wall may have any desired number of recesses of any desired shape and at any desired points. For this purpose, examples of a cavity are not only a box or a compartment but also a hollow hemisphere, a cage or a lattice ball.

For the purposes of the description of the present invention, a flange of a housing means a part of a housing which is used for connecting or coupling the housing to other physical units, for sealing or for closing the housing. In particular, the term includes the (rear) flange parts of a motor housing, into which an electronics assembly is intended to be installed or is installed.

For the purposes of the description of the present invention, an electronic assembly means a physical unit, and frequently also a functional unit, which is formed from integrated and/or discrete, active and/or passive components, which are electrically and mechanically connected by a network of lines on a wiring mount. Within an electronic or electrical appliance, the assembly therefore forms the hierarchy level which follows the electronic components. Important examples of electronic assemblies are so-called electronic printed circuit board assemblies. An electronic printed circuit board assembly means an assembly comprising electronic components, mechanically connected by a rigid, generally flat and insulating substrate, in the form of a so-called board, in or on which conductor tracks for electrical connection of the components are arranged.

For the purposes of the description of the present invention, a depression, in particular a depression in a wall of a cavity, means any shape of a first physical element which is suitable for allowing an elastically deformable tab on a second physical element, in particular an elastically deformable tab on a housing cover, to latch into this depression. In this case, the process of the tab latching in restricts the movement capabilities of the element which is equipped with this tab. Examples of such depressions are bounded areas in a wall, which areas have a material thickness which is less than that of the rest of the wall.

For the purposes of the description of the present invention, an elastically deformable tab means a shaped element which is designed such that it can latch into a depression, in particular into a depression in a wall of a cavity. The process of the tab latching in in this case results in a restriction to the movement capabilities of the element which is equipped with this tab. Other designations, with which a person skilled in the art will likewise be familiar, for such shaped elements are, for example, tongue, leaf, snapper or similar terms.

For the purposes of the description of the present invention, a housing cover means a physical element of a housing which is designed such that it is suitable for at least partially bounding a cavity in a housing on the outside, for example to close it or to cover it.

All of the terms used in this description of the present invention should be understood as also covering the other meanings which a person skilled in the art would normally associate with these terms.

Advantageous developments of the invention form the subject matter of dependent claims.

The invention will be explained in more detail in the following text using preferred exemplary embodiments and with the aid of the figures, in which:

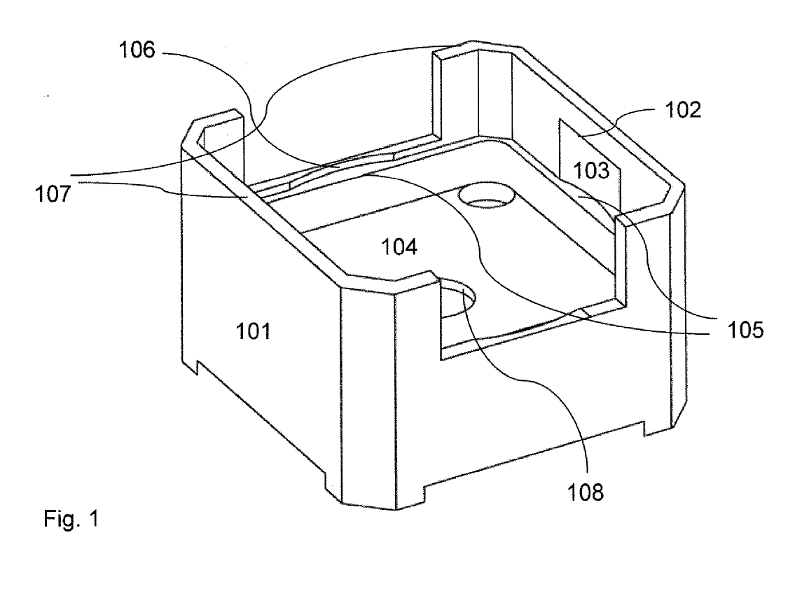

FIG. 1 shows a housing flange with a cavity according to one preferred exemplary embodiment of the present invention;

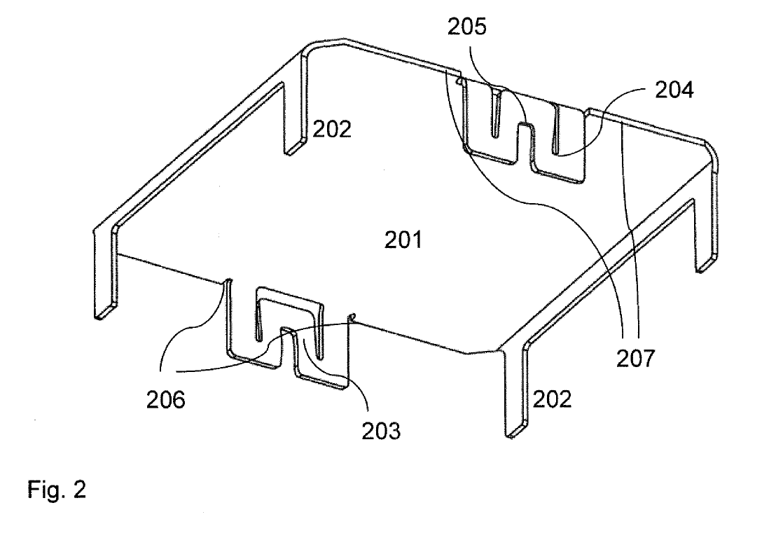

FIG. 2 shows a housing cover, according to one preferred exemplary embodiment of the present invention;

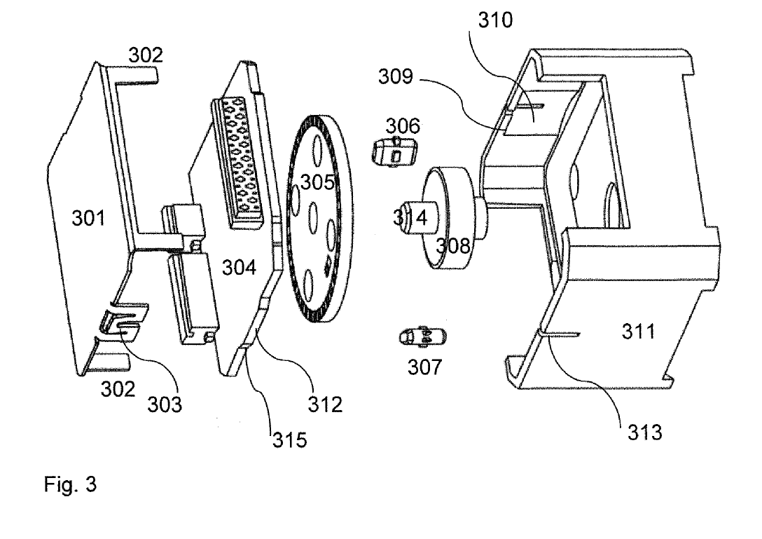

FIG. 3 shows an exploded illustration of a housing flange of an electric motor having a housing cover and installed parts according to one preferred exemplary embodiment of the present invention;

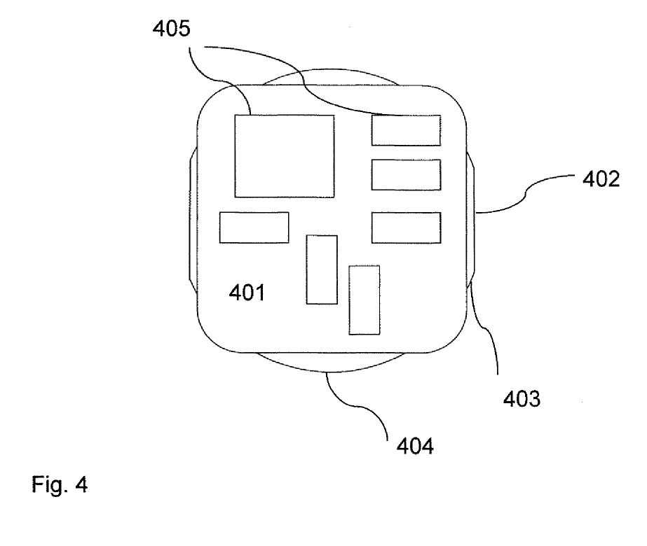

FIG. 4 shows a schematic illustration of an electronic assembly according to one preferred exemplary embodiment of the invention.

As is shown in FIGS. 1 to 4 with reference to one preferred embodiment of the invention, the rear flange part 101, 311—also referred to in the following text simply as a flange—of an electric motor is designed such that an electronic assembly having components 405 can be installed in a cavity in this flange. For this purpose, this cavity is bounded on the motor side by a base plate 104, which may have a plurality of openings for cables or plugs, or may in particular have an opening 108 through which the motor shaft is passed.

At the sides, this cavity is bounded by walls 107 in parts of which depressions 103, 310 are incorporated. These depressions in the walls of the cavity are preferably turned-out areas 103, 310 in the form of cylinder segments and are bounded in the axial direction by an upper edge 102, 309 and a lower edge 105, with the lower edge preferably forming a circumferential step 105 for an electronic assembly 304 to rest on. Recesses 106 are preferably located in this step, and are preferably turned-out areas 106 in the form of circle segments.

Turned-out areas 103, 310 in the form of cylinder segments are, however, only one possibility within the scope of one preferred embodiment of the invention. For example, if the flange is reworked using a milling machine instead of a lathe, other boundary surfaces may also be advantageous, because such configurations in some circumstances make it unnecessary to insert the printed circuit board assembly obliquely in order to allow the secant 402 to pass the upper wall edge 102. In particular, this is unnecessary when the upper wall edge 102 is slightly offset outwards.

The motor shaft 314 is passed through the opening 108 in the base plate 104. In this case, in contrast to the situation illustrated in FIG. 3, the bearing normally remains under the base plate. Plugs 306 or connectors 307 for cables for connection of the motor winding wires can be passed through further openings in the base plate. A magnetic encoder disk 305 rotates on the shaft 314 and an electronic assembly 304 can be arranged in the vicinity of this encoder disk 305, which electronic assembly 304 has a sensor for detecting the movements and/or the angular position of the encoder disk.

This assembly, which is expediently in the form of a so-called printed circuit board assembly 304, rests on the step 105 of the flange 101, 311. If the housing cover 301 is now plugged into the flange, then the supports 202, 302 which are fitted to the housing cover press the electronic assembly 304 which is resting on the step against the step, as a result of which the electronic assembly 304 which is resting on this step is fixed, as soon as the elastically deformable tabs 203, 303 on the housing cover 201 have latched into the depressions 103, 310.

The housing cover is preferably a sheet-metal cover which has tabs 203 which, as snappers, latch into the depressions 103, 310. In this embodiment of the invention, no screws are therefore required for attachment of the housing cover. In this case, the tabs 203 can be produced by stamping in appropriate notches 204, 205, 206, in which case, after being stamped in, the tabs are typically slightly angled, for example by a few degrees, and are therefore, for example, angled with respect to the lug. If, as is shown for example in FIG. 2, these notches 206 are of suitable shape, the housing cover projects slightly over 207 after the tabs have been bent. If this is desirable, these projections 207 can rest on the upper edges 107 of the walls, or can end with them.

Only one additional clamping-in process is necessary on a lathe, that is to say one additional processing step, to produce the flange, preferably based on aluminum die-casting technology. However, the flange can also be produced in other ways, for example by milling.

On the motor side, the flange holds the rear bearing of the motor shaft and ends the motor area on the outside. On the other side, the flange forms a cavity, in which motor electronics in the form of an electronic printed circuit board assembly can be accommodated. The connections of the motor winding are preferably passed through openings in the base plate 104 of the flange.

Preferred embodiments of the invention in which, for example, the depressions in the walls of the cavity are turned-out areas 103 in the form of cylinder segments, or in which, for example, the circumferential step has recesses 106 for positioning of an appropriately shaped electronic assembly, which recesses are turned-out areas 106 in the form of circle segments, are associated with various advantages. For example, a flange designed in this way can be produced with a very small number of processing steps and therefore at very low cost, by turning a cylindrical part out from the casting. This step requires clamping in only once in a lathe. A corresponding configuration of the electronic printed circuit board assembly, with rounded areas 315 applied at the sides and which can engage in the turned-out areas 106 in the form of circle segments, allows this printed circuit board assembly to be positioned over these circle segments. These circle segments can easily be turned out with the aid of a lathe from the casting from which the flange is produced, and this can be done with high precision. In the axial direction, the printed circuit board assembly 304 rests on the circumferential step 105 in the casting.

Instead of now screwing the printed circuit board assembly tight in the axial direction, the housing cover is now preferably used, according to the invention, as a spring with latching. In this case, supports 202 which are fitted to the housing cover press the printed circuit board assembly 304 against the step 105 as soon as the elastically deformable tabs 203 on the housing cover 201 have latched into the depressions 103. If the step is appropriately arranged with respect to the upper edge 107 of the walls or with respect to the upper edges 102, 309 of the depressions 103, 310, an electronic assembly 304 which has been placed on this step is fixed by this pressure of the supports. This also makes it possible to provide a seal which, for example, protects an optical encoder sensor, when only the printed circuit board assembly rests all round flush on the step.

There is therefore no need for any of the screws for the printed circuit board assembly or for the housing cover, either. The housing cover itself can be produced as a simple bent part from sheet metal. Stainless steel, for example with a thickness of 0.5 mm, is preferably used. The spring deflection is preferably about 0.6 mm. The housing cover is correspondingly inserted preferably somewhat deeper into the flange, in order that it does not overhang the flange when in the stressed state.

The electronic printed circuit board assembly is preferably equipped at its edges with shapes 315, 403, 404 which are in the form of circle segments, into which shapes turned-out areas 106, which are in the form of circle segments, in the flange 101 fit. This simplifies high-precision positioning of the printed circuit board assembly, as is required in particular in the case of appliances with an angle sensor, in order that it can operate reliably and accurately. In these situations, high-precision lateral positioning of the printed circuit board assembly is actually very important while, in contrast, rotation of this assembly about the rotation axis of the motor is insignificant, provided that this does not take place during operation. In order to make it easier to insert the printed circuit board assembly into the flange, some of these circle lines 403, 404 may be cut off in the form of secants 312, 402.

According to one preferred embodiment of the invention, recesses 313 or holes in the form of slots or notches can be provided in the area of the depressions 310 in the walls 107 of the cavity, extending from the upper edge of the respective wall so far in the direction of the base 104 of the cavity that, by insertion of a narrow object, it is possible to push the tab 203 which has been latched into this depression away from the depression, thus allowing the housing cover to be unlocked and therefore removed.

An encoder disk 305 occupies a relatively large area, which is not available for the motor wires to be passed through to the printed circuit board assembly. One preferred embodiment of the invention therefore provides for the braids of the motor windings to be passed in pairs through the base plate 104 in two corners. In order to ensure that the wires do not touch metal, they are preferably routed in a plastic injection-molded part 306 or in an insulating flexible tube. The injection-molded part or the flexible tube preferably extends as far as under the board of the printed circuit board assembly, as a result of which the board can easily be plugged onto it, and the wires can be soldered directly to the connecting pads on the printed circuit board—for example manually.

1. Housing for an electrical appliance having a cavity in a flange (101) of the housing for holding an electronic assembly (304), characterized in that the cavity has walls (107) which each have a depression (103) which are designed such that elastically deformable tabs (203) on a housing cover (201), which at least partially bounds the cavity on the outside, can latch into these depressions.

2. Housing according to claim 1, in which the depressions (103) are designed such that elastically deformable tabs (203) on a housing cover (201), which ends with the upper edge (107) of the walls or rests on this upper edge, can latch into these depressions.

3. Housing according to claim 1, in which the cavity has a circumferential step (105) for an electronic assembly (304) to rest on.

4. Housing according to claim 3, in which the step (105) is arranged with respect to the upper edge (107) of the walls such that an electronic assembly (304) which is resting on this step is fixed by supports (202) which are fitted to the housing cover, as soon as the elastically deformable tabs (203) on the housing cover (201) have latched into the depressions (103).

5. Housing according to claim 1, in which the depressions in the walls of the cavity are turned out areas (103) in the form of cylinder segments.

6. Housing according to claim 2, in which the circumferential step has recesses (106) for positioning of an appropriately shaped electronic assembly.

7. Housing according to claim 6, in which the recesses in the step are turned out areas (106) in the foam of circle segments.

8. Housing according to claim 2, in which the cavity has a circumferential step (105) for an electronic assembly (304) to rest on.

9. Housing according to claim 2, in which the depressions in the walls of the cavity are turned out areas (103) in the form of cylinder segments.

10. Housing according to claim 3, in which the depressions in the walls of the cavity are turned out areas (103) in the form of cylinder segments.

11. Housing according to claim 4, in which the depressions in the walls of the cavity are turned out areas (103) in the form of cylinder segments.

12. Housing according to claim 3, in which the circumferential step has recesses (106) for positioning of an appropriately shaped electronic assembly.

13. Housing according to claim 4, in which the circumferential step has recesses (106) for positioning of an appropriately shaped electronic assembly.

14. Housing according to claim 5, in which the circumferential step has recesses (106) for positioning of an appropriately shaped electronic assembly.
